(19) United States
(12) Patent Application Publication
(10) Pub. No.: US 2024/0224634 A1
(43) Pub. Date: Jul. 4, 2024

(54) DISPLAY PANEL AND REPAIRING METHOD OF DISPLAY PANEL

(71) Applicant: Shenzhen China Star Optoelectronics Semiconductor Display Technology Co., Ltd., Shenzhen, Guangdong (CN)

(72) Inventor: Jiexin ZHENG, Shenzhen, Guangdong (CN)

(21) Appl. No.: 17/756,525

(22) PCT Filed: May 13, 2022
(86) PCT No.: PCT/CN2022/092666

§ 371 Date: Nov. 2, 2023

(51) Int. Cl. H10K 59/131; H10K 59/121; H10K 59/126; H10K 71/00

(52) U.S. Cl. CPC H10K 59/131; H10K 59/1213; H10K 59/126; H10K 71/861

(57) ABSTRACT

The present application provides a display panel and a repairing method thereof. The display panel has a light-emitting area and a non-light-emitting area disposed adjacent to each other, wherein the display panel includes a transistor layer and a light-emitting structure layer disposed in a stack; the light-emitting structure layer includes a lower electrode and an upper electrode; the transistor layer includes an epitaxial conductor part, a first electrode, and a second electrode; the first electrode is spaced from the second electrode, and one of the first electrode or the second electrode is connected to the epitaxial conductor part and the lower electrode; and the epitaxial conductor part and the upper electrode are located in the non-light-emitting area and are disposed correspondingly.

### BACKGROUND OF INVENTION

### Field of Invention

The present application relates to a field of display technology, and particularly to a display panel and a repairing method of the display panel.

### Description of Prior Art

At present, in manufacturing processes of light-emitting diodes display panels, due to existences of metal residues, broken wires, or foreign objects, a problem of poor bright-spots occurs in the light-emitting diodes display panels during lighting stages of devices. The light-emitting diodes include organic light-emitting diodes and inorganic light-emitting diodes. Existing repairing methods of the poor bright-spots usually adopt a way of cutting off power lines or forming a short-circuit between an anode and a cathode, however, when using the existing repairing methods to repair the poor bright-spots, since operations are cumbersome, resulting in low repairing efficiency.

### SUMMARY OF INVENTION

The present application provides a display panel and a repairing method of the display panel to improve efficiency of repairing poor bright-spots.

The present application provides a display panel, wherein the display panel includes a plurality of sub-pixels, each of the sub-pixels includes a light-emitting area and a non-light-emitting area disposed adjacent to each other, and the display panel includes:
a substrate;
a transistor layer disposed on the substrate, wherein the transistor layer includes a transistor and an epitaxial conductor part, the transistor is located in the light-emitting area, and the transistor includes a first electrode and a second electrode disposed in a same layer and spaced apart: the epitaxial conductor part is located in the non-light-emitting area: and the transistor further includes an active part located below the first electrode; the epitaxial conductor part includes a first epitaxial part, the active part is connected to the first epitaxial part, and the active part is connected to the first electrode or the second electrode: and
a light-emitting structure layer disposed on the transistor layer, the light-emitting structure layer includes a lower electrode and an upper electrode disposed in a stack, the lower electrode is connected to the first electrode or the second electrode, and the upper electrode extends from the light-emitting area to the non-light-emitting area,
wherein an orthographic projection of the epitaxial conductor part on the substrate at least partially overlaps an orthographic projection of the upper electrode on the substrate.

Alternatively, in some embodiments of the present application, the transistor further includes a light shielding part located below the first electrode, the epitaxial conductor part further includes a second epitaxial part, the light shielding part is connected to the second epitaxial part, and the light shielding part is connected to the first electrode or the second electrode.

Alternatively, in some embodiments of the present application, the transistor further includes a gate insulating part and a gate electrode, the first epitaxial part is composed of the active part extending towards the non-light-emitting area, and the gate insulating part and the gate electrode are sequentially stacked on the active part.

Alternatively, in some embodiments of the present application, the transistor layer further includes a metal conducting part, the metal conducting part is disposed between the first epitaxial part and the upper electrode, and the metal conducting part is spaced from the gate electrode: and the metal conducting part is connected to the first epitaxial part and insulated from the upper electrode, the gate electrode and the metal conducting part are manufactured by one process, and the metal conducting part, the first epitaxial part, and the upper electrode are disposed correspondingly.

Alternatively, in some embodiments of the present application, the display panel further includes a pixel definition layer, the pixel definition layer is disposed on the transistor layer and the lower electrode, the pixel definition layer is defined with an auxiliary electrode hole, and the auxiliary electrode hole is located in the non-light-emitting area: and the auxiliary electrode hole passes through the pixel definition layer, the auxiliary electrode hole is provided corresponding to the first epitaxial part and the metal conducting part, the upper electrode is disposed on the pixel definition layer, and the upper electrode extends into the auxiliary electrode hole.

Alternatively, in some embodiments of the present application, the display panel further includes a connecting structure, the connecting structure is disposed between the upper electrode and the metal conducting part, the connecting structure is insulated from the upper electrode and the metal conducting part, and the connecting structure, the first epitaxial part, the metal conducting part, and the upper electrode are disposed correspondingly.

Alternatively, in some embodiments of the present application, the connecting structure includes a connecting electrode, the connecting electrode is disposed on the transistor layer, and the connecting electrode and the lower electrode are disposed in a same layer and spaced apart.

Alternatively, in some embodiments of the present application, the connecting structure includes a switching part and a first conducting part connected to the switching part, the switching part is disposed on a side of the first conducting part close to the upper electrode, and the switching part, the first electrode, and the second electrode are disposed in a same layer and spaced apart.

Alternatively, in some embodiments of the present application, the transistor further includes a light shielding part, the light shielding part is disposed corresponding to the active part, and the light shielding part is connected to the first electrode: and the first electrode is connected to an end of the active part and the upper electrode, the second electrode is connected to the first epitaxial part and another end of the active part, and an orthographic projection of the active part on the substrate is staggered with an orthographic projection of the first epitaxial part on the substrate.

Accordingly, the present application further provides a display panel, wherein the display panel includes a plurality of sub-pixels, each of the sub-pixels includes a light-emitting area and a non-light-emitting area disposed adjacent to each other, and the display panel includes:
a substrate;
a transistor layer disposed on the substrate, wherein the transistor layer includes a transistor and an epitaxial conductor part, the transistor is located in the light-emitting area, and the transistor includes a first electrode and a second electrode disposed in a same layer and spaced apart: the epitaxial conductor part is located in the non-light-emitting area: and the transistor further includes an active part located below the first electrode, the epitaxial conductor part includes a first epitaxial part, the active part is connected to the first epitaxial part, and the active part is connected to the first electrode or the second electrode: and
a light-emitting structure layer disposed on the transistor layer, wherein the light-emitting structure layer includes a lower electrode and an upper electrode disposed in a stack, the lower electrode is connected to the first electrode or the second electrode, the upper electrode extends from the light-emitting area to the non-light-emitting area, and the upper electrode is connected to the epitaxial conductor part.

Alternatively, in some embodiments of the present application, the first epitaxial part is composed of the active part extending towards the non-light-emitting area: the transistor layer further includes a metal conducting part, the metal conducting part is disposed on the first epitaxial part, and the metal conducting part is connected to the upper electrode and the first epitaxial part.

Alternatively, in some embodiments of the present application, the transistor further includes a gate insulating part and a gate electrode, the gate insulating part and the gate electrode are sequentially stacked on the active part, the gate electrode is spaced from the metal conducting part, and the gate electrode and the metal conducting part are manufactured by one process.

Alternatively, in some embodiments of the present application, the display panel further includes a pixel definition layer, the pixel definition layer is disposed on the transistor layer and the lower electrode: the pixel definition layer is defined with an auxiliary electrode hole, and the auxiliary electrode hole is located in the non-light-emitting area: and the auxiliary electrode hole passes through the pixel definition layer, the auxiliary electrode hole is provided corresponding to the first epitaxial part, the upper electrode is disposed on the pixel definition layer, and the upper electrode extends into the auxiliary electrode hole and is connected to the first epitaxial part.

Alternatively, in some embodiments of the present application, the display panel further includes a connecting structure, the connecting structure is disposed between the pixel definition layer and the first epitaxial part, and the connecting structure is connected to the upper electrode and the first epitaxial part.

Alternatively, in some embodiments of the present application, the connecting structure includes a connecting electrode, the connecting electrode is disposed on the transistor layer, and the connecting electrode, and the lower electrode are disposed in a same layer and spaced apart.

Alternatively, in some embodiments of the present application, the connecting structure includes a switching part and a first conducting part connected to the switching part, the switching part is disposed on a side of the first conducting part close to the upper electrode, and the switching part, the first electrode and the second electrode are disposed in a same layer and spaced apart.

Alternatively, in some embodiments of the present application, the transistor further includes a light shielding part, the light shielding part is disposed corresponding to the active part, and the light shielding part is connected to the first electrode: and the first electrode is connected to an end of the active part and the upper electrode, the second electrode is connected to the first epitaxial part and another end of the active part, and an orthographic projection of the active part on the substrate is staggered with an orthographic projection of the first epitaxial part on the substrate.

Alternatively, in some embodiments of the present application, the transistor further includes a light shielding part located below the first electrode, the epitaxial conductor part further includes a second epitaxial part, the light shielding part is connected to the second epitaxial part, and the light shielding part is connected to the first electrode or the second electrode.

Accordingly, the present application further provides a display panel, including:
providing a panel to be repaired, wherein the panel to be repaired includes a plurality of sub-pixels, each of the sub-pixels includes a light-emitting area and a non-light-emitting area disposed adjacent to each other, and the panel to be repaired includes:
a substrate;
a transistor layer disposed on the substrate, wherein the transistor layer includes a transistor and an epitaxial conductor part, the transistor is located in the light-emitting area, and the transistor includes a first electrode and a second electrode disposed in a same layer and spaced apart: the epitaxial conductor part is located in the non-light-emitting area; and the transistor further includes an active part located below the first electrode; the epitaxial conductor part includes a first epitaxial part, the active part is connected to the first epitaxial part, and the active part is connected to the first electrode or the second electrode: and
a light-emitting structure layer disposed on the transistor layer, the light-emitting structure layer includes a lower electrode and an upper electrode disposed in a stack, the lower electrode is connected to the first electrode or the second electrode, and the upper electrode extends from the light-emitting area to the non-light-emitting area,
wherein an orthographic projection of the epitaxial conductor part on the substrate at least partially overlaps an orthographic projection of the upper electrode on the substrate: and
connecting the epitaxial conductor part with the upper electrode.

Alternatively, in some embodiments of the present application, the step of connecting the epitaxial conductor part with the upper electrode includes: irradiating the epitaxial conductor part and the upper electrode by laser to connect the epitaxial conductor part with the upper electrode.

The present application provides the display panel and the repairing method of the display panel. Wherein the display panel includes the plurality of sub-pixels, each of the sub-pixels includes the light-emitting area and the non-light-emitting area disposed adjacent to each other: the display panel includes the substrate, the transistor layer, and the light-emitting structure layer disposed in a stack: the transistor layer is disposed on the substrate, wherein the transistor layer includes the transistor and the epitaxial conductor part, the transistor is located in the light-emitting area, and the transistor includes the first electrode and the second electrode disposed in the same layer and spaced apart: the epitaxial conductor part is located in the non-light-emitting area: the transistor further includes the active part located below the first electrode, the epitaxial conductor part includes the first epitaxial part, the active part is connected to the first epitaxial part, and the active part is connected to the first electrode or the second electrode: the light-emitting structure layer is disposed on the transistor layer, wherein the light-emitting structure layer includes the lower electrode and the upper electrode disposed in a stack, the lower electrode is connected to the first electrode or the second electrode, and the upper electrode extends from the light-emitting area to the non-light-emitting area, wherein the orthographic projection of the epitaxial conductor part on the substrate at least partially overlaps the orthographic projection of the upper electrode on the substrate. In the present application, by disposing the epitaxial conductor part connected to the transistor, and the orthographic projection of the epitaxial conductor part on the substrate and the orthographic projection of the upper electrode on the substrate being at least partially overlapping, when the display panel has the poor bright-spots, the epitaxial conductor part can be connected to the upper electrode in a laser overlapping region formed between the epitaxial conductor part and the upper electrode, thereby repairing the display panel and improving a success rate of repairing the poor bright-spots.

### BRIEF DESCRIPTION OF DRAWINGS

In order to clearly explain technical solutions in embodiments of the present application, the following will briefly introduce drawings needed to be used in descriptions of the embodiments. It is obvious that the drawings in the following descriptions are only some embodiments of the present application. For those skilled in the art, other drawings can be obtained according to these drawings without paying creative labor.

FIG. 1 is a first schematic structural diagram of a display panel provided by an embodiment of the present application.

FIG. 2 is a second schematic structural diagram of the display panel provided by an embodiment of the present application.

FIG. 3 is a third schematic structural diagram of the display panel provided by an embodiment of the present application.

FIG. 4 is a schematic structural diagram of the display panel provided by an embodiment of the present application.

FIG. 5 is a flowchart of a repairing method of the display panel provided by the embodiment of the present application.

FIG. 6 is a schematic flow diagram of a manufacturing method of the display panel provided by the embodiment of the present application.

### DESCRIPTION OF REFERENCE MARKS

a display panel 10; a light-emitting area 11: a non-light-emitting area 12: a substrate 100; a transistor layer 200; a light shielding part 201: a first electrode plate 202; a buffer layer 203: an epitaxial conductor part 204; a first epitaxial part 2041; a second epitaxial part 2042: an active part 205: a semiconductor part 205a: a conductor part 205b: a second electrode plate 206: a gate insulating part 207: a metal conducting part 208: a gate electrode 209; an interlayer dielectric layer 210: a switching part 211; a first electrode 212: a second electrode 213: a passivation layer 214: a first conducting part 215: a second conducting part 216: a planarization layer 217: a connecting electrode 218: a first through hole 219: a second through hole 220; a third through hole 221: a fourth through hole 222: a sixth through hole 224; a seventh through hole 225: a fifth through hole 223: a pixel definition layer 300; an auxiliary electrode hole 301; a via 302: a light-emitting structure layer 400; a lower electrode 410: a light-emitting layer 420: and an upper electrode 430.

### DETAILED DESCRIPTION OF EMBODIMENTS

Technical solutions in embodiments of the present application will be described clearly and completely below in combination with attached drawings in the embodiment of the present application. Obviously, the described embodiments are only part of the embodiments of the present application, not all of the embodiments. Based on the embodiments in the present application, all other embodiments obtained by those skilled in the art without creative work belong to a scope of a protection of the present application. In addition, it should be understood that the specific embodiments described herein are only used to illustrate and explain the present application and are not used to limit the present application. In the present application, in the absence of a contrary explanation, location words used, such as “up” and “down”, usually refer to up and down under actual uses or working states of devices, specifically drawing directions in the attached drawings: and words “inside” and “outside” are referred to contours of the devices. In the present application, “reaction” can be a chemical reaction or a physical reaction.

The present application provides a display panel and a repairing method of the display panel. Wherein the display panel includes a plurality of sub-pixels, each of the sub-pixels includes a light-emitting area and a non-light-emitting area disposed adjacent to each other: the display panel includes a substrate, a transistor layer, and a light-emitting structure layer disposed in a stack: the transistor layer is disposed on the substrate, the transistor layer includes a transistor and an epitaxial conductor part, and the transistor includes a first electrode and a second electrode disposed in a same layer and spaced apart: the epitaxial conductor part is located in the non-light-emitting area: the transistor further includes an active part located below the first electrode, the epitaxial conductor part includes a first epitaxial part, the active part is connected to the first epitaxial part, and the active part is connected to the first electrode or the second electrode: the light-emitting structure layer is disposed on the transistor layer, wherein the light-emitting structure layer includes a lower electrode and an upper electrode disposed in a stack, the lower electrode is connected to the first electrode, and the upper electrode extends from the light-emitting area to the non-light-emitting area, wherein an orthographic projection of the epitaxial conductor part on the substrate at least partially overlaps an orthographic projection of the upper electrode on the substrate.

In the present application, by disposing the epitaxial conductor part connected to the transistor, and the orthographic projection of the epitaxial conductor part on the substrate and the orthographic projection of the upper electrode on the substrate being at least partially overlapping, when the display panel has poor bright-spots, the epitaxial conductor part can be connected to the upper electrode in a laser overlapping region, thereby repairing the bright-spots of the display panel and improving a success rate of repairing the poor bright-spots.

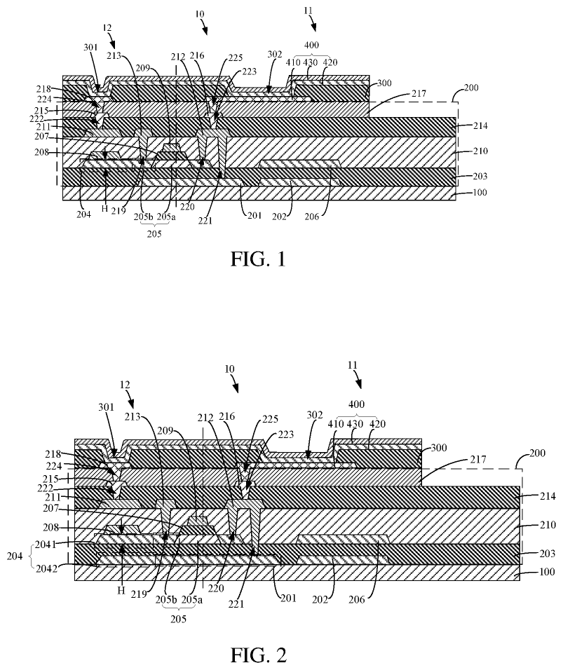

Referring to FIG. 1, the present application provides a display panel 10. The display panel 10 includes a plurality of sub-pixels, and each of the sub-pixels includes a light-emitting area 11 and a non-light-emitting area 12 disposed adjacent to each other. The display panel 10 includes a substrate 100, a transistor layer 200, a pixel definition layer 300, and a light-emitting structure layer 400.

The transistor layer 200 is disposed on the substrate 100. The transistor layer 200 includes a transistor and an epitaxial conductor part 204. The transistor is located in the light-emitting area 11 and the non-light-emitting area 12. The transistor includes a first electrode 212 and a second electrode 213 disposed in a same layer and spaced apart. The epitaxial conductor part 204 is located in the non-light-emitting area 12. The transistor further includes an active part 205 located below the first electrode 212. The epitaxial conductor part 204 includes a first epitaxial part 2041. The active part 205 is connected to the first epitaxial part 2041, and the active part 205 is connected to the first electrode 212 or the second electrode 213. Specifically, the epitaxial conductor part 204 includes the first epitaxial part 2041. The active part 205 is connected to the first epitaxial part 2041, and the active part 205 is connected to one of the first electrode 212 and the second electrode 213, wherein the first epitaxial part 2041 is composed of the active part 205 extending towards the non-light-emitting area 12. The transistor layer 200 includes a light shielding part 201, a first electrode plate 202, a buffer layer 203, the first epitaxial part 2041, the active part 205, a second electrode plate 206, a gate insulating part 207, a metal conducting part 208, a gate electrode 209, an interlayer dielectric layer 210, a switching part 211, the first electrode 212, the second electrode 213, a passivation layer 214, a first conducting part 215, a second conducting part 216, a planarization layer 217, and a connecting electrode 218. The active part 205 includes a semiconductor part 205a and conductor parts 205b disposed on both sides of the semiconductor part 205a. The first conducting part 215, the switching part 211, and the connecting electrode 218 constitute a connecting structure of the display panel 10. The light shielding part 201, the active part 205, the gate insulating part 207, the gate electrode 209, the first electrode 212, and the second electrode 213 constitute the transistor of the transistor layer 200. A plurality of transistors are disposed in the transistor layer 200 in a same layer and spaced apart. In the present embodiment, the transistor is a top-gate structure transistor.

Specifically, the light shielding part 201 and the first electrode plate 202 are disposed on the substrate 100 in a same layer and spaced apart. The first electrode plate 202 is located in the light-emitting area 11. The first electrode plate 202 and the light shielding part 201 are formed of same metal materials. Materials of the first electrode plate 202 and materials of the light shielding part 201 both include one or a combination of Cu and a MoTi alloy. Alternatively, the materials of the first electrode plate 202 and the materials of the light shielding part 201 can also be other materials.

Subsequently, the buffer layer 203 is disposed on the light shielding part 201, the first electrode plate 202, and the substrate 100.

Subsequently, the active part 205, the first epitaxial part 2041, and the second electrode plate 206 are disposed in a same layer and spaced apart. The first epitaxial part 2041 is connected to the conductor parts 205b. The first epitaxial part 2041 is located in the non-light-emitting area 12. The first epitaxial part 2041 is formed by extending the semiconductor part 205a to the non-light-emitting area 12. An orthographic projection of the first epitaxial part 2041 on the substrate 100 is a first projection. An orthographic projection of the upper electrode 430 on the substrate 100 is a second projection. The first projection at least partially overlaps the second projection. The first epitaxial part 2041 is configured to be irradiated by laser when repairing poor bright-spots, so that the first epitaxial part 2041 can be connected to a subsequent upper electrode 430, thereby forming a short-circuit between the first epitaxial part 2041 and the upper electrode 430. Wherein the laser is a laser. The semiconductor part 205a is located above the light shielding part 201. The second electrode plate 206 is located above the first electrode plate 202. The active part 205, the first epitaxial part 2041, and the second electrode plate 206 are formed of same materials and manufactured by a same mask. The active part 205, the first epitaxial part 2041, and the second electrode plate 206 include one of metal oxide, amorphous silicon, or polycrystalline silicon. The metal oxide is indium gallium zinc oxide or indium gallium tin oxide, etc. Optionally, the metal oxide can also be other materials.

In the present application, by disposing the first epitaxial part 2041 formed by extending the conductor parts 205b to the non-light-emitting area 12, the first epitaxial part 2041 can be used as a repairing electrode to repair the poor bright-spots. Wherein the active part 205 and the first epitaxial part 2041 can be formed by a same mask process without using another mask process to form the repairing electrode for repairing the poor bright-spots, thereby simplifying a process of the display panel 10 and shortening a production cycle of the display panel 10, so as to reduce production cost of the display panel 10.

Please continue to refer to FIG. 1, in an embodiment, a thickness H of the first epitaxial part 2041, a thickness of the active part 205, and a thickness of the second electrode plate 206 are same. The thickness H of the active part 205, the first epitaxial part 2041, and the second electrode plate 206 ranges from 100 nm to 300 nm. Specifically, the thickness H of the active part 205, the first epitaxial part 2041, and the second electrode plate 206 can be 100 nm, 150 nm, 200 nm, 250 nm, or 300 nm, etc.

In the present application, the thickness H of the first epitaxial part 2041 is configured to range from 100 nm to 300 nm. Due to the thickness of the first epitaxial part 2041 being thin, only a small amount of laser energy is needed to connect the first epitaxial part 2041 with the upper electrode 430 when using the first epitaxial part 2041 to repair the poor bright-spots, so as to form a short-circuit between the first epitaxial part 2041 and the upper electrode 430, thereby improving a repairing success rate.

Please continue to refer to FIG. 1, subsequently, the gate insulating part 207 is disposed on the semiconductor part 205a.

Please continue to refer to FIG. 1, subsequently, the metal conducting part 208 is disposed on the first epitaxial part 2041. The metal conducting part 208 is configured to connect the first epitaxial part 2041 with the upper electrode 430 when repairing the poor bright-spots. The gate electrode 209 is disposed on the gate insulating part 207 and spaced from the metal conducting part 208. The first epitaxial part 2041, the metal conducting part 208, and the upper electrode 430 are disposed correspondingly. An orthographic projection of the metal conducting part 208 on the substrate 100 is a third projection, and the third projection at least partially coincides with the first projection and the second projection.

It should be noted that words “disposed correspondingly” indicates that one film layer is located directly above or below another film layer.

In the present application, the first epitaxial part 2041 is composed of metal oxide, polycrystalline silicon, or amorphous silicon, and the upper electrode 430 is composed of metal. When repairing the poor bright-spots, since the first epitaxial part 2041 is not composed of metal, it can cause difficult conduction between the first epitaxial part 2041 and the upper electrode 430. By disposing the metal conducting part 208 in direct contact with the first epitaxial part 2041 on the first epitaxial part 2041, since the metal conducting part 208 is composed of metal, an electrical signal of the upper electrode 430 can be well transmitted to the first epitaxial part 2041, which makes it easy to form the short-circuit between the first epitaxial part 2041 and the upper electrode 430, thereby further improving the success rate of repairing the poor bright-spots.

Please continue to refer to FIG. 1, subsequently, the interlayer dielectric layer 210 is disposed on the buffer layer 203, the first epitaxial part 2041, the active part 205, the second electrode plate 206, the gate insulating part 207, the metal conducting part 208, and the gate electrode 209. The interlayer dielectric layer 210 is defined with a first through hole 219, a second through hole 220, and a third through hole 221. The first through hole 219 penetrates the interlayer dielectric layer 210 to expose the conductor parts 205b connected to the first epitaxial part 2041. The second through hole 220 penetrates the interlayer dielectric layer 210 to expose the conductor parts 205b located away from the first epitaxial part 2041. The third through hole 221 penetrates the interlayer dielectric layer 210 and the buffer layer 203 to expose the light shielding part 201. The second through hole 220 and the third through hole 221 are located on one side of the semiconductor part 205a. The first through hole 219 is located on another side of the semiconductor part 205a.

Please continue to refer to FIG. 1, subsequently, the first electrode 212, the second electrode 213, and the switching part 211 are disposed on the interlayer dielectric layer 210 in a same layer and spaced apart. The second electrode 213 is located between the first electrode 212 and the switching part 211. The second electrode 213 extends into the first through hole 219 and is connected to the conductor parts 205b connected to the first epitaxial part 2041. The first electrode 212 extends into the second through hole 220 and the third through hole 221 and is connected to the conductor parts 205b and the light shielding part 201. The first electrode 212 is located in the light-emitting area 11. The switching part 211 is located in the non-light-emitting area 12. The switching part 211, the first epitaxial part 2041, the metal conducting part 208, and the upper electrode 430 are disposed correspondingly. That is, an orthographic projection of the switching part 211 on the substrate 100 at least partially overlaps the first projection and the second projection, and an orthographic projection of the connecting structure on the substrate 100 at least partially overlaps the third projection, the first projection, and the second projection. The first electrode 212 is a source electrode, and the second electrode 213 is a drain electrode.

In another embodiment, the first electrode 212 is a drain electrode, and the second electrode 213 is a source electrode.

Please continue to refer to FIG. 1, subsequently, the passivation layer 214 is disposed on the switching part 211, the first electrode 212, and the second electrode 213. The passivation layer 214 is provided with a fourth through hole 222 and a fifth through hole 223. The fourth through hole 222 penetrates the passivation layer 214 to expose the switching part 211. The fifth through hole 223 penetrates the passivation layer 214 to expose the first electrode 212.

Please continue to refer to FIG. 1, subsequently, the first conducting part 215 and the second conducting part 216 are disposed on the passivation layer 214 in a same layer and spaced apart. The first conducting part 215 extends into the fourth through hole 222 and is connected to the switching part 211. The first conducting part 215, the first epitaxial part 2041, the metal conducting part 208, and the upper electrode 430 are disposed correspondingly. That is, an orthographic projection of the first conducting part 215 on the substrate 100 at least partially overlaps the first projection and the second projection, and the orthographic projection of the connecting structure on the substrate 100 at least partially overlaps the first projection and the second projection. The second conducting part 216 extends into the fifth through hole 223 and is connected to the first electrode 212. The first conducting part 215 and the second conducting part 216 are formed of same metal materials. Materials of the first conducting part 216 and materials of the second conducting part 215 both include a MoTi alloy Alternatively, the materials of the first conducting part 215 and the materials of the second conducting part 216 can also be other materials.

Please continue to refer to FIG. 1, subsequently, the planarization layer 217 is disposed on the passivation layer 214, the first conducting part 215, and the second conducting part 216. The planarization layer 217 is provided with a sixth through hole 224 and a seventh through hole 225. The sixth through hole 224 penetrates the planarization layer 217 to expose the first conducting part 215. The seventh through hole 225 penetrates the planarization layer 217 to expose the second conducting part 216.

Please continue to refer to FIG. 1, the light-emitting structure layer 400 is disposed on the transistor layer 200. The light-emitting structure layer 400 includes a lower electrode 410 and the upper electrode 430 disposed in a stack. The lower electrode 410 is connected to the first electrode 212. The upper electrode 430 extends from the light-emitting area 11 to the non-light-emitting area 12. Specifically, the light-emitting structure layer 400 includes a plurality of light-emitting structure parts. Each of the light-emitting structure parts is connected to one transistor. Each of the light-emitting structure parts includes the lower electrode 410, a light-emitting layer 420, and the upper electrode 430, that is, the light-emitting structure layer 400 includes the lower electrode 410, the light-emitting layer 420, and the upper electrode 430. The connecting electrode 218 and the lower electrode 410 are disposed on the planarization layer 217 in a same layer and spaced apart. The connecting electrode 218 extends into the sixth through hole 224 and is connected to the first conducting part 215. An orthographic projection of the connecting electrode 218 on the substrate 100 at least partially overlaps the first projection and the second projection, that is, the orthographic projection of the connecting structure on the substrate 100 at least partially overlaps the first projection and the second projection. The lower electrode 410 extends into the seventh through hole 225 and is connected to the second conducting part 216.

Subsequently, the pixel definition layer 300 is disposed on the planarization layer 217, the lower electrode 410, and the connecting electrode 218. The pixel definition layer 300 is defined with an auxiliary electrode hole 301 and a via 302. The auxiliary electrode hole 301 penetrates the pixel definition layer 300 to expose the connecting electrode 218. The auxiliary electrode hole 301 is provided corresponding to the metal conducting part 208 and the first epitaxial part 2041. The via 302 penetrates the pixel definition layer 300 to expose the lower electrode 410. The light-emitting layer 420 is disposed on the pixel definition layer 300 and extends into the auxiliary electrode hole 301 and the via 302 to connect with the connecting electrode 218 and the lower electrode 410 respectively. The light-emitting layer 420 is an organic light-emitting layer. The upper electrode 430 is disposed on the light-emitting layer 420 and extends into the auxiliary electrode hole 301. The upper electrode 430 located in the auxiliary electrode hole 301 is an auxiliary electrode. The second projection, the first projection, the third projection, and the orthographic projection of the connecting structure on the substrate 100 at least partially overlap. The lower electrode 410 is a reflective anode and the upper electrode 430 is a transparent cathode.

In an embodiment, materials of the lower electrode 410 and materials of the connecting electrode 218 are same. The materials of the lower electrode 410 and the materials of the connecting electrode 218 both include one or more combinations of indium zinc oxide, silver, and indium tin oxide. The materials of the lower electrode 410 and the materials of the connecting electrode 218 can also be other materials. The lower electrode 410 and the connecting electrode 218 can be composed of multi-layers, such as an indium zinc oxide layer, a silver layer, and an indium zinc oxide layer disposed in a stack.

In the present embodiment, the display panel 10 is a top-emitting display panel.

In another embodiment, the display panel 10 is a bottom-emitting display panel. The lower electrode 410 is a transparent anode, and the upper electrode 430 is a reflective cathode.

When the display panel 10 has the poor bright-spots, by irradiating an overlapping region formed of the first projection, the second projection, the third projection, and the orthographic projection of the connecting structure on the substrate 100 with the laser, the first epitaxial part 2041 can be connected to the metal conducting part 208, the connecting structure, and the upper electrode 430, so as to achieve a darkening of the bright-spots of the display panel 10.

In the present application, by disposing the first epitaxial part 2041 connected to the transistor, and at least partially overlapping the first projection and the second projection, so that when the display panel 10 has the poor bright-spots, by irradiating the first epitaxial part 2041 with the laser on a side of the substrate 100 away from the light-emitting structure 400, the first epitaxial part 2041 can be connected to the upper electrode 430, so as to achieve a purpose of repairing the poor bright-spots and reduce difficulty of repairing the poor bright-spots. At a same time, laser irradiating is only needed once to connect the first epitaxial part 2041 with the upper electrode 430, which can save time required for repairing, thereby improving efficiency of repairing the poor bright-spots. Since the first epitaxial part 2041 is formed by extending the semiconductor part 205a to the non-light-emitting area 12, manufacturing process of the display panel 10 does not need to increase, thereby shortening the production cycle, making it conducive to rapid preparation of the display panel 10, saving a number of masks, and reducing the production cost. By disposing the metal conducting part 208 on the first epitaxial part 2041, and the third projection, the first projection, and the second projection being at least partially overlapping, since the metal conducting part 208 is composed of metal, the first epitaxial part 2041 and the upper electrode 430 can be easily conducted, so that the electrical signal of the upper electrode 430 can be well transmitted to the first epitaxial part 2041, thereby further improving the success rate of repairing the poor bright-spots.

In the present application, by disposing the connecting structure between the first epitaxial part 2041 and the upper electrode 430, and the orthographic projection of the connecting structure on the substrate 100, the first projection, the second projection, and the third projection being at least partially overlapping, when repairing the poor bright-spots, the connecting structure can be used as an intermediate transition structure, which can shorten a conducting distance between the first epitaxial part 2041 and the upper electrode 430, so as to further improve the repairing success rate. At a same time, since the first conducting part 215 is disposed in the fourth through hole 222 of the passivation layer 214, and the connecting electrode 218 is disposed in the sixth through hole 224 of the planarization layer 217, a number of insulating layers through which energy passes during laser repairing can be decreased, thereby further improving the success rate of repairing the poor bright-spots.

In the present application, the auxiliary electrode hole 301 is provided on the pixel definition layer 300, and the auxiliary electrode hole 301 is located directly above the first epitaxial part 2041. When repairing the poor bright-spots, repairing points can be determined according to a position of the auxiliary electrode hole 301, which can prevent the laser irradiating other metal layers, or more time needed to find the repairing points, so as to improve accuracy and the efficiency of repairing the poor bright-spots. By disposing the auxiliary electrode hole 301 on the pixel definition layer 300, since the auxiliary electrode hole 301 passes through the pixel definition layer 300, the number of insulating layers the laser needs to pass through is further decreased, thereby improving the success rate of repairing the poor bright-spots.

It should be noted that film structures of the display panel 10 of the present application can be removed as needed, such as the connecting structure, the passivation layer 214, the planarization layer 217, and the interlayer dielectric layer 210, etc.

Referring to FIG. 2, it should be noted that differences between a second structure and a first structure mentioned above are: the epitaxial conductor part 204 further includes a second epitaxial part 2042. The light shielding part 201 is connected to the second epitaxial part 2042, and the light shielding part 201 is connected to one of the first electrode 212 and the second electrode 213. Specifically, the second epitaxial part 2042 is located directly below the first epitaxial part 2041. The second epitaxial part 2042 is composed of the light shielding part 201 extending towards the non-light-emitting area 12, and the second epitaxial part 2042 is connected to the light shielding part 201. The orthographic projection of the first epitaxial part 2041 on the substrate 100 at least partially overlaps an orthographic projection of the second epitaxial part 2042 on the substrate 100, and the orthographic projection of the first epitaxial part 2041 on the substrate 100, the orthographic projection of the second epitaxial part 2042 on the substrate 100, the orthographic projection of the connecting structure on the substrate 100, and the orthographic projection of the upper electrode 430 on the substrate 100 at least partially overlap. Other structures are same as the first structure, which will not be repeated here.

In the present application, the first epitaxial part 2041 and the second epitaxial part 2042 constitute the epitaxial conductor part 204. When repairing poor bright-spots, the epitaxial conductor part 204 is used as a transition part located between the second epitaxial part 2042 and the upper electrode 430, which can shorten a conducting distance between the second epitaxial part 2042 and the upper electrode 430, so as to further improve the success rate of repairing the poor bright-spots.

When the display panel 10 has the poor bright-spots, by irradiating the overlapping region formed of the first projection, the second projection, the third projection, and the orthographic projection of the connecting structure on the substrate 100 with laser, the second epitaxial part 2042 can be connected to the first epitaxial part 2041, the metal conducting part 208, the connecting structure, and the upper electrode 430, thereby achieving a darkening of the bright-spots of the display panel 10.

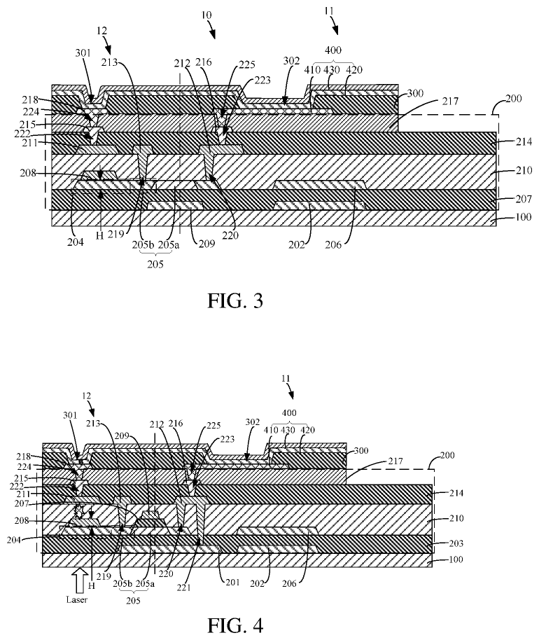

Referring to FIG. 3, it should be noted that differences between a third structure and the first structure are: the transistor is a bottom gate structure transistor. The buffer layer 203 and the light shielding part 201 are removed from the third structure. The gate electrode 209 is disposed at a position where the light shielding part 201 is located. The gate insulating part 207 is disposed at a position where the buffer layer 203 is located. The first electrode 212 is only connected to the conductor parts 205b. Other structures are same as the first structure and will not be repeated here.

When the display panel 10 has the poor bright-spots, by irradiating the overlapping region formed of the first projection, the second projection, the third projection, and the orthographic projection of the connecting structure on the substrate 100 with laser, the second epitaxial part 2042 can be connected to the metal conducting part 208, the connecting structure, and the upper electrode 430, thereby achieving the darkening of the bright-spots of the display panel 10.

The present application provides the display panel 10, by disposing the epitaxial conductor part 204 connected to the transistor, and connecting the epitaxial conductor part 204 with the upper electrode 430, the bright-spots of the display panel 10 can be darkened, so as to solve a problem of the poor bright-spots of the display panel 10, and reduce the difficulty of repairing the poor bright-spots. At a same time, laser irradiating is only needed once to connect the epitaxial conductor part 204 with the upper electrode 430, saving the time required for repairing, thereby improving the efficiency of repairing the poor bright-spots. Since the first epitaxial part 2041 is formed by extending the semiconductor part 205a to the non-light-emitting area 12, the manufacturing process of the display panel 10 does not need to increase, thereby shortening the production cycle, making it conducive to the rapid preparation of the display panel 10, saving the number of masks, and reducing the production cost.

The present application further provides a display panel, the display panel includes a plurality of sub-pixels, each of the sub-pixels includes a light-emitting area and a non-light-emitting area disposed adjacent to each other: the display panel includes a substrate, a transistor layer, and a light-emitting structure layer disposed in a stack; the transistor layer is disposed on the substrate, the transistor layer includes a transistor and an epitaxial conductor part, the transistor is located in the light-emitting area, and the transistor includes a first electrode and a second electrode disposed in a same layer and spaced apart: the epitaxial conductor part is located in the non-light-emitting area; the transistor further includes an active part located below the first electrode, the epitaxial conductor part includes a first epitaxial part, the active part is connected to the first epitaxial part, and the active part is connected to the first electrode or the second electrode: the light-emitting structure layer is disposed on the transistor layer, wherein the light-emitting structure layer includes a lower electrode and an upper electrode disposed in a stack, the lower electrode is connected to the first electrode or the second electrode, the upper electrode extends from the light-emitting area to the non-light-emitting area, and the upper electrode is connected to the epitaxial conductor part.

In the present application, by connecting the epitaxial conductor part to the active part, the active part is connected to the first electrode or the second electrode, one of the first electrode or the second electrode is connected to the lower electrode, the lower electrode is connected to the upper electrode, the upper electrode extends to the non-light-emitting area, and an orthographic projection of the upper electrode on the substrate at least partially coincides with an orthographic projection of the epitaxial conductor part on the substrate. After irradiating the epitaxial conductor part with laser, the epitaxial conductor part is connected to the upper electrode to form a short-circuit, so as to darken bright-spots of the display panel, thereby solving a problem of the poor bright-spots of the display panel and improving a success rate of repairing the poor bright-spots.

Referring to FIG. 4, the present application provides a display panel 10. The display panel 10 provided in FIG. 4 of the present application is a display panel 10 formed after laser repairing the display panel 10 provided in FIG. 1 of the present application. The display panel 10 includes the plurality of sub-pixels, and each of the sub-pixels includes the light-emitting area 11 and the non-light-emitting area 12 disposed adjacent to each other. The display panel 10 includes the substrate 100, the transistor layer 200, the pixel definition layer 300, and the light-emitting structure layer 400.

The transistor layer 200 is disposed on the substrate 100. The transistor layer 200 includes the transistor and the first epitaxial part 2041. The transistor includes the first electrode 212 and the second electrode 213 disposed in a same layer and spaced apart. The first epitaxial part 2041 is located in the non-light-emitting area 12. The transistor further includes the active part 205 located below the first electrode 212. The epitaxial conductor part 204 includes the first epitaxial part 2041. The active part 205 is connected to the first epitaxial part 2041, and the active part 205 is connected to the first electrode 212 or the second electrode 213. The first epitaxial part 2041 is composed of the active part 205 extending towards the non-light-emitting area 12.

Specifically, the transistor layer 200 includes the light shielding part 201, the first electrode plate 202, the buffer layer 203, the first epitaxial part 2041, the active part 205, the second electrode plate 206, the gate insulating part 207, the metal conducting part 208, the gate electrode 209, the interlayer dielectric layer 210, the switching part 211, the first electrode 212, the second electrode 213, the passivation layer 214, the first conducting part 215, the second conducting part 216, the planarization layer 217, and the connecting electrode 218. The active part 205 includes the semiconductor part 205a and the conductor parts 205b disposed on both sides of the semiconductor part 205a. The first conducting part 215, the switching part 211, and the connecting electrode 218 constitute the connecting structure of the display panel 10. The light shielding part 201, the active part 205, the gate insulating part 207, the gate electrode 209, the first electrode 212, and the second electrode 213 constitute the transistor of the transistor layer 200. A plurality of transistors are disposed in the transistor layer 200 in a same layer and spaced apart.

Specifically, the light shielding part 201 and the first electrode plate 202 are disposed on the substrate 100 in a same layer and spaced apart. The first electrode plate 202 is located in the light-emitting area 11. The first electrode plate 202 and the light shielding part 201 are formed of same metal materials. Materials of the first electrode plate 202 and materials of the light shielding part 201 both include one or a combination of Cu and a MoTi alloy. Alternatively, the materials of the first electrode plate 202 and the materials of the light shielding part 201 can also be other materials.

Subsequently, the buffer layer 203 is disposed on the light shielding part 201, the first electrode plate 202, and the substrate 100.

Subsequently, the active part 205, the first epitaxial part 2041, and the second electrode plate 206 are disposed in a same layer and spaced apart. The first epitaxial part 2041 is connected to the conductor parts 205b. The first epitaxial part 2041 is located in the non-light-emitting area 12. The first epitaxial part 2041 is formed by extending the semiconductor part 205a to the non-light-emitting area 12. The first epitaxial part 2041 is connected to the upper electrode 430 which is directly disposed above the first epitaxial part 2041. The semiconductor part 205a is located above the light shielding part 201. The second electrode plate 206 is located above the first electrode plate 202. The active part 205, the first epitaxial part 2041, and the second electrode plate 206 are formed of same materials. The active part 205, the first epitaxial part 2041, and the second electrode plate 206 include one of metal oxide, amorphous silicon, or polycrystalline silicon. The metal oxide is indium gallium zinc oxide or indium gallium tin oxide, etc. Optionally, the metal oxide can also be other materials.

Please continue to refer to FIG. 4, in an embodiment, the thickness H of the first epitaxial part 2041, a thickness of the active part 205, and a thickness of the second electrode plate 206 are same. The thickness H of the active part 205, the first epitaxial part 2041, and the second electrode plate 206 ranges from 100 nm to 300 nm. Specifically, the thickness H of the active part 205, the first epitaxial part 2041, and the second electrode plate 206 can be 100 nm, 150 nm, 200 nm, 250 nm, or 300 nm, etc.

In the present application, the thickness H of the first epitaxial part 2041 is configured to range from 100 nm to 300 nm. Due to the thickness of the first epitaxial part 2041 being thin, only a small amount of laser energy is needed to connect the first epitaxial part 2041 with the upper electrode 430 when using the first epitaxial part 2041 to repair the poor bright-spots, so as to form a short-circuit between the first epitaxial part 2041 and the upper electrode 430, thereby improving a repairing success rate.

Please continue to refer to FIG. 4, subsequently, the gate insulating part 207 is disposed on the semiconductor part 205a.

Please continue to refer to FIG. 4, subsequently, the metal conducting part 208 is disposed on the first epitaxial part 2041. The metal conducting part 208 is connected to the first epitaxial part 2041 and the upper electrode 430. The gate electrode 209 is disposed on the gate insulating part 207 and spaced from the metal conducting part 208.

In the present application, since the first epitaxial part 2041 is not composed of metal, and the upper electrode 430 is composed of metal, by disposing the metal conducting part 208 on the first epitaxial part 2041 and directly contacting the first epitaxial part 2041, the first epitaxial part 2041 and the upper electrode 430 can be easily conducted, so that an electrical signal of the upper electrode 430 can be well transmitted to the first epitaxial part 2041, thereby further improving the success rate of repairing the poor bright-spots.

Please continue to refer to FIG. 4, subsequently, the interlayer dielectric layer 210 is disposed on the buffer layer 203, the first epitaxial part 2041, the active part 205, the second electrode plate 206, the gate insulating part 207, the metal conducting part 208, and the gate electrode 209. The interlayer dielectric layer 210 is defined with the first through hole 219, the second through hole 220, and the third through hole 221. The first through hole 219 penetrates the interlayer dielectric layer 210 to expose the conductor parts 205b connected to the first epitaxial part 2041. The second through hole 220 penetrates the interlayer dielectric layer 210 to expose the conductor parts 205b located away from the first epitaxial part 2041. The third through hole 221 penetrates the interlayer dielectric layer 210 and the buffer layer 203 to expose the light shielding part 201. The second through hole 220 and the third through hole 221 are located on one side of the semiconductor part 205a. The first through hole 219 is located on another side of the semiconductor part 205a.

Please continue to refer to FIG. 4, subsequently, the first electrode 212, the second electrode 213, and the switching part 211 are disposed on the interlayer dielectric layer 210 in a same layer and spaced apart. The second electrode 213 is located between the first electrode 212 and the switching part 211. The second electrode 213 extends into the first through hole 219 and is connected to the conductor parts 205b connected to the first epitaxial part 2041. The first electrode 212 extends into the second through hole 220 and the third through hole 221 and is connected to the conductor parts 205b and the light shielding part 201. The first electrode 212 is located in the light-emitting area 11. The switching part 211 is located in the non-light-emitting area 12, and is located directly above the first epitaxial part 2041 and the metal conducting part 208, and the switching part 211 is connected to the upper electrode 430 and the metal conducting part 208. That is, the connecting structure is located directly above the first epitaxial part 2041 and the metal conducting part 208, and the connecting structure is connected to the upper electrode 430 and the metal conducting part 208. The first electrode 212 is the source electrode, and the second electrode 213 is the drain electrode.

In another embodiment, the first electrode 212 is the drain electrode, and the second electrode 213 is the source electrode.

Please continue to refer to FIG. 4, subsequently, the passivation layer 214 is disposed on the switching part 211, the first electrode 212, and the second electrode 213. The passivation layer 214 is provided with a fourth through hole 222 and a fifth through hole 223. The fourth through hole 222 penetrates the passivation layer 214 to expose the switching part 211. The fifth through hole 223 penetrates the passivation layer 214 to expose the first electrode 212.

Please continue to refer to FIG. 4, subsequently, the first conducting part 215 and the second conducting part 216 are disposed on the passivation layer 214 in a same layer and spaced apart. The first conducting part 215 extends into the fourth through hole 222 and is connected to the switching part 211. The first conducting part 215 is connected to the switching part 211 and the upper electrode 430. The second conducting part 216 extends into the fifth through hole 223 and is connected to the first electrode 212. The first conducting part 215 and the second conducting part 216 are formed of same metal materials. Materials of the first conducting part 216 and materials of the second conducting part 215 both include a MoTi alloy. Alternatively, the materials of the first conducting part 215 and the materials of the second conducting part 216 can also be other materials.

Please continue to refer to FIG. 4, subsequently, the planarization layer 217 is disposed on the passivation layer 214, the first conducting part 215, and the second conducting part 216. The planarization layer 217 is provided with a sixth through hole 224 and a seventh through hole 225. The sixth through hole 224 penetrates the planarization layer 217 to expose the first conducting part 215. The seventh through hole 225 penetrates the planarization layer 217 to expose the second conducting part 216.

Please continue to refer to FIG. 4, the light-emitting structure layer 400 is disposed on the transistor layer 200. The light-emitting structure layer 400 includes a lower electrode 410 and the upper electrode 430 disposed in a stack. The lower electrode 410 is connected to the first electrode 212. The upper electrode 430 extends from the light-emitting area 11 to the non-light-emitting area 12. Specifically, the light-emitting structure layer 400 includes a plurality of light-emitting structure parts. Each of the light-emitting structure parts is connected to one transistor. Each of the light-emitting structure parts includes the lower electrode 410, a light-emitting layer 420, and the upper electrode 430, that is, the light-emitting structure layer 400 includes the lower electrode 410, the light-emitting layer 420, and the upper electrode 430. The connecting electrode 218 and the lower electrode 410 are disposed on the planarization layer 217 in a same layer and spaced apart. The connecting electrode 218 extends into the sixth through hole 224, is connected to the first conducting part 215, and is connected to the upper electrode 430. The lower electrode 410 extends into the seventh through hole 225 and is connected to the second conducting part 216.

Subsequently, the pixel definition layer 300 is disposed on the planarization layer 217, the lower electrode 410, and the connecting electrode 218. The pixel definition layer 300 is defined with the auxiliary electrode hole 301 and the via 302. The auxiliary electrode hole 301 penetrates the pixel definition layer 300 to expose the connecting electrode 218. The auxiliary electrode hole 301 is provided corresponding to the metal conducting part 208 and the first epitaxial part 2041. The via 302 penetrates the pixel definition layer 300 to expose the lower electrode 410. The light-emitting layer 420 is disposed on the pixel definition layer 300 and extends into the auxiliary electrode hole 301 and the via 302 to connect with the connecting electrode 218 and the lower electrode 410 respectively. The light-emitting layer 420 is an organic light-emitting layer 420. The upper electrode 430 is disposed on the light-emitting layer 420 and extends into the auxiliary electrode hole 301 and is connected to the connecting electrode 218. The upper electrode 430 located in the auxiliary electrode hole 301 is the auxiliary electrode. The lower electrode 410 is the reflective anode and the upper electrode 430 is the transparent cathode.

In an embodiment, materials of the lower electrode 410 and materials of the connecting electrode 218 are same. The materials of the lower electrode 410 and the materials of the connecting electrode 218 both include one or more combinations of indium zinc oxide, silver, and indium tin oxide. The materials of the lower electrode 410 and the materials of the connecting electrode 218 can also be other materials. The lower electrode 410 and the connecting electrode 218 can be composed of multi-layers, such as an indium zinc oxide layer, a silver layer, and an indium zinc oxide layer disposed in a stack.

In the present embodiment, the display panel 10 is the top-emitting display panel.

In another embodiment, the display panel 10 is the bottom-emitting display panel. The lower electrode 410 is the transparent anode, and the upper electrode 430 is the reflective cathode.

In the present application, by disposing the first epitaxial conductor part 2041 connected to the transistor, and the first epitaxial conductor part 2041 connecting with the upper electrode 430, thereby darkening the bright-spots of the display panel 10, a problem of the poor bright-spots of the display panel 10 is solved, while reducing difficulty of repairing the poor bright-spots. At a same time, laser irradiating is only needed once to connect the first epitaxial conductor part 2041 with the upper electrode 430, which can save time required for repairing, thereby improving efficiency of repairing the poor bright-spots. Since the first epitaxial part 2041 is formed by extending the semiconductor part 205a to the non-light-emitting area 12, the manufacturing process of the display panel 10 does not need to increase, thereby shortening a production cycle, making it conducive to manufacture the display panel 10 rapidly, saving a number of masks, and reducing production cost. By disposing the metal conducting part 208 on the first epitaxial part 2041 and connecting to it, since the metal conducting part 208 is composed of metal, the first epitaxial part 2041 and the upper electrode 430 can be easily conducted, so that an electrical signal of the upper electrode 430 can be well transmitted to the first epitaxial part 2041, thereby further improving a success rate of repairing the poor bright-spots.

In the present application, by disposing the connecting structure between the first epitaxial part 2041 and the upper electrode 430, the connecting structure can be used as the intermediate transition structure, causing the connecting structure to be connected to the first epitaxial part 2041 and the upper electrode 430, which can shorten the conducting distance between the first epitaxial part 2041 and the upper electrode 430, thereby further improving the repairing success rate. At a same time, since the first conducting part 215 is disposed in the fourth through hole 222 of the passivation layer 214, and the connecting electrode 218 is disposed in the sixth through hole 224 of the planarization layer 217, a number of insulating layers through which energy passes during laser repairing can be decreased, thereby further improving the success rate of repairing the poor bright-spots.

In the present application, the auxiliary electrode hole 301 is provided on the pixel definition layer 300, and the auxiliary electrode hole 301 is located directly above the first epitaxial part 2041. When repairing the poor bright-spots, repairing points can be determined according to a position of the auxiliary electrode hole 301, which can prevent the laser irradiating other metal layers, or more time needed to find the repairing points, so as to improve accuracy and the efficiency of repairing the poor bright-spots. By disposing the auxiliary electrode hole 301 on the pixel definition layer 300, since the auxiliary electrode hole 301 passes through the pixel definition layer 300, the number of insulating layers the laser needs to pass through is further decreased, thereby improving the success rate of repairing the poor bright-spots.

It should be noted that film structures of the display panel 10 of the present application can be removed as needed, such as the connecting structure, the passivation layer 214, the planarization layer 217, and the interlayer dielectric layer 210, etc.

The present application further provides a repairing method of a display panel to repair the display panel provided by the present application. The repairing method of the display panel includes following steps:

B11: providing a panel to be repaired, the panel to be repaired includes a plurality of sub-pixels, each of the sub-pixels includes a light-emitting area and a non-light-emitting area disposed adjacent to each other, and the panel to be repaired includes:
a substrate;
a transistor layer disposed on the substrate, the transistor layer includes a transistor and an epitaxial conductor part, the transistor is located in the light-emitting area, and the transistor includes a first electrode and a second electrode disposed in a same layer and spaced apart: the epitaxial conductor part is located in the non-light-emitting area: and the transistor further includes an active part located below the first electrode, the epitaxial conductor part includes a first epitaxial part, the active part is connected to the first epitaxial part, and the active part is connected to the first electrode or the second electrode; and
a light-emitting structure layer disposed on the transistor layer, the light-emitting structure layer includes a lower electrode and an upper electrode disposed in a stack, the lower electrode is connected to the first electrode or the second electrode, and the upper electrode extends from the light-emitting area to the non-light-emitting area,
wherein an orthographic projection of the epitaxial conductor part on the substrate is a first projection, an orthographic projection of the upper electrode on the substrate is a second projection, and the first projection and the second projection at least partially overlap.

B12: connecting the epitaxial conductor part with the upper electrode.

In the present application, by disposing the epitaxial conductor part connected to the transistor, and the first projection and the second projection being at least partially overlapping, when the display panel has poor bright-spots, the epitaxial conductor part can be connected to the upper electrode in a laser overlapping region, thereby repairing the display panel and improving a success rate of repairing the poor bright-spots.

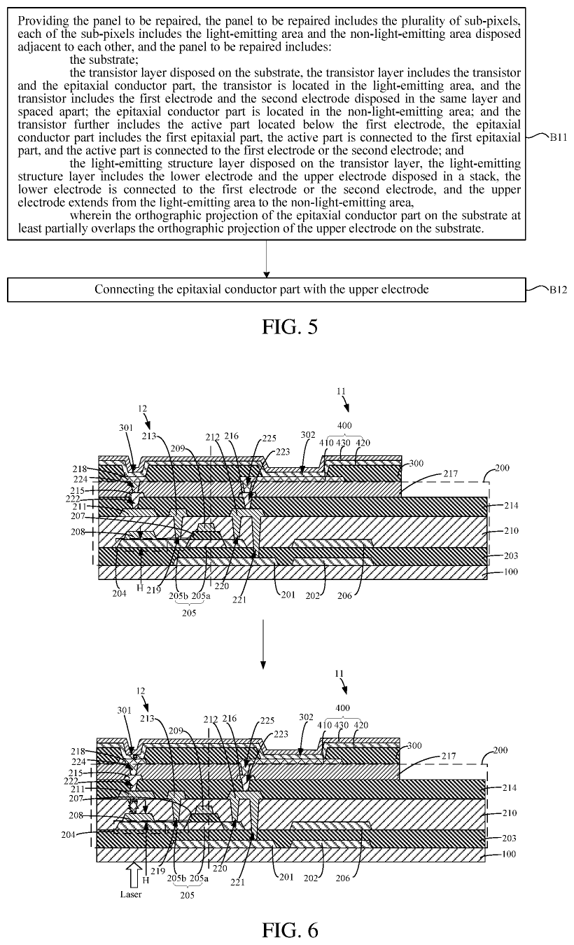

Refer to FIG. 5 and FIG. 6. The present application further provides the repairing method of the display panel to repair the display panel 10 provided by the present application. The repairing method of the display panel includes following steps:

B11: providing the panel to be repaired, the panel to be repaired includes the plurality of sub-pixels, each of the sub-pixels includes the light-emitting area and the non-light-emitting area disposed adjacent to each other, and the panel to be repaired includes:
the substrate;
the transistor layer disposed on the substrate, the transistor layer includes the transistor and the epitaxial conductor part, the transistor is located in the light-emitting area, and the transistor includes the first electrode and the second electrode disposed in the same layer and spaced apart: the epitaxial conductor part is located in the non-light-emitting area: and the transistor further includes the active part located below the first electrode, the epitaxial conductor part includes the first epitaxial part, the active part is connected to the first epitaxial part, and the active part is connected to the first electrode or the second electrode; and
the light-emitting structure layer disposed on the transistor layer, the light-emitting structure layer includes the lower electrode and the upper electrode disposed in a stack, the lower electrode is connected to the first electrode or the second electrode, and the upper electrode extends from the light-emitting area to the non-light-emitting area,
wherein the orthographic projection of the epitaxial conductor part on the substrate at least partially overlaps the orthographic projection of the upper electrode on the substrate.

The panel to be repaired 20 includes the substrate 100, the transistor layer 200, and the light-emitting structure layer 400.

The transistor layer 200 is disposed on the substrate 100. The transistor layer 200 includes the transistor and an epitaxial conductor part 204. The transistor includes the first electrode 212 and the second electrode 213 disposed in a same layer and spaced apart. The transistor further includes the active part 205 located below the first electrode 212. The epitaxial conductor part 204 includes the first epitaxial part 2041. The active part 205 is connected to the first epitaxial part 2041, and the active part 205 is connected to the first electrode 212 or the second electrode 213.

Specifically, the transistor layer 200 includes a light shielding part 201, a first electrode plate 202, a buffer layer 203, the first epitaxial part 2041, the active part 205, a second electrode plate 206, a gate insulating part 207, a metal conducting part 208, a gate electrode 209, an interlayer dielectric layer 210, a switching part 211, the first electrode 212, the second electrode 213, a passivation layer 214, a first conducting part 215, a second conducting part 216, a planarization layer 217, and a connecting electrode 218. The active part 205 includes a semiconductor part 205a and conductor parts 205b disposed on both sides of the semiconductor part 205a. The first conducting part 215, the switching part 211, and the connecting electrode 218 constitute a connecting structure. The light shielding part 201, the active part 205, the gate insulating part 207, the gate electrode 209, the first electrode 212, and the second electrode 213 constitute the transistor of the transistor layer 200. A plurality of transistors are disposed in the transistor layer 200 in a same layer and spaced apart. In the present embodiment, the transistor is a top-gate structure transistor.

Specifically, the light shielding part 201 and the first electrode plate 202 are disposed on the substrate 100 in a same layer and spaced apart. The first electrode plate 202 is located in the light-emitting area 11. The first electrode plate 202 and the light shielding part 201 are formed of same metal materials. Materials of the first electrode plate 202 and materials of the light shielding part 201 both include one or a combination of Cu and a MoTi alloy. Alternatively, the materials of the first electrode plate 202 and the materials of the light shielding part 201 can also be other materials.

Subsequently, the buffer layer 203 is disposed on the light shielding part 201, the first electrode plate 202, and the substrate 100.

Subsequently, the active part 205, the first epitaxial part 2041, and the second electrode plate 206 are disposed in a same layer and spaced apart. The first epitaxial part 2041 is connected to the conductor parts 205b. The first epitaxial part 2041 is located in the non-light-emitting area 12. The first epitaxial part 2041 is formed by extending the semiconductor part 205a to the non-light-emitting area 12. An orthographic projection of the first epitaxial part 2041 on the substrate 100 is a first projection. An orthographic projection of the upper electrode 430 on the substrate 100 is a second projection. The first projection at least partially overlaps the second projection. The first epitaxial part 2041 is configured to be irradiated by laser when repairing the poor bright-spots, so that the first epitaxial part 2041 can be connected to a subsequent upper electrode 430, thereby forming a short-circuit between the first epitaxial part 2041 and the upper electrode 430. Wherein the laser is a laser. The semiconductor part 205a is located above the light shielding part 201. The second electrode plate 206 is located above the first electrode plate 202. The active part 205, the first epitaxial part 2041, and the second electrode plate 206 are formed of same materials and manufactured by a same mask. The active part 205, the first epitaxial part 2041, and the second electrode plate 206 include one of metal oxide, amorphous silicon or polycrystalline silicon. The metal oxide is indium gallium zinc oxide, or indium gallium tin oxide, etc. Optionally, the metal oxide can also be other materials.

In an embodiment, a thickness H of the first epitaxial part 2041, a thickness of the active part 205, and a thickness of the second electrode plate 206 are same. The thickness H of the active part 205, the first epitaxial part 2041, and the second electrode plate 206 ranges from 100 nm to 300 nm. Specifically, the thickness H of the active part 205, the first epitaxial part 2041, and the second electrode plate 206 can be 100 nm, 150 nm, 200 nm, 250 nm, or 300 nm, etc.

Subsequently, the gate insulating part 207 is disposed on the semiconductor part 205a.

Subsequently, the metal conducting part 208 is disposed on the first epitaxial part 2041. The metal conducting part 208 is configured to connect the first epitaxial part 2041 with the upper electrode 430 when repairing the poor bright-spots. The gate electrode 209 is disposed on the gate insulating part 207 and spaced from the metal conducting part 208. An orthographic projection of the metal conducting part 208 on the substrate 100 is a third projection, and the third projection at least partially coincides with the first projection and the second projection.

Subsequently, the interlayer dielectric layer 210 is disposed on the buffer layer 203, the first epitaxial part 2041, the active part 205, the second electrode plate 206, the gate insulating part 207, the metal conducting part 208, and the gate electrode 209. The interlayer dielectric layer 210 is defined with a first through hole 219, a second through hole 220, and a third through hole 221. The first through hole 219 penetrates the interlayer dielectric layer 210 to expose the conductor parts 205b connected to the first epitaxial part 2041. The second through hole 220 penetrates the interlayer dielectric layer 210 to expose the conductor parts 205b located away from the first epitaxial part 2041. The third through hole 221 penetrates the interlayer dielectric layer 210 and the buffer layer 203 to expose the light shielding part 201. The second through hole 220 and the third through hole 221 are located on one side of the semiconductor part 205a. The first through hole 219 is located on another side of the semiconductor part 205a.

Subsequently, the first electrode 212, the second electrode 213, and the switching part 211 are disposed on the interlayer dielectric layer 210 in a same layer and spaced apart. The second electrode 213 is located between the first electrode 212 and the switching part 211. The second electrode 213 extends into the first through hole 219 and is connected to the conductor parts 205b connected to the first epitaxial part 2041. The first electrode 212 extends into the second through hole 220 and the third through hole 221 and is connected to the conductor parts 205b and the light shielding part 201. The first electrode 212 is located in the light-emitting area 11. The switching part 211 is located in the non-light-emitting area 12. An orthographic projection of the switching part 211 on the substrate 100 at least partially overlaps the first projection and the second projection, and an orthographic projection of the connecting structure on the substrate 100 at least partially overlaps the third projection, the first projection, and the second projection. The first electrode 212 is a source electrode, and the second electrode 213 is a drain electrode.

Subsequently, the passivation layer 214 is disposed on the switching part 211, the first electrode 212, and the second electrode 213. The passivation layer 214 is defined with a fourth through hole 222 and a fifth through hole 223. The fourth through hole 222 penetrates the passivation layer 214 to expose the switching part 211. The fifth through hole 223 penetrates the passivation layer 214 to expose the first electrode 212.

Subsequently, the first conducting part 215 and the second conducting part 216 are disposed on the passivation layer 214 in a same layer and spaced apart. The first conducting part 215 extends into the fourth through hole 222 and is connected to the switching part 211. An orthographic projection of the first conducting part 215 on the substrate 100 at least partially overlaps the first projection and the second projection, that is, the orthographic projection of the connecting structure on the substrate 100 at least partially overlaps the first projection and the second projection. The second conducting part 216 extends into the fifth through hole 223 and is connected to the first electrode 212. The first conducting part 215 and the second conducting part 216 are formed of same metal materials. Materials of the first conducting part 216 and materials of the second conducting part 215 both include a MoTi alloy. Alternatively, the materials of the first conducting part 215 and the materials of the second conducting part 216 can also be other materials.

Subsequently, the planarization layer 217 is disposed on the passivation layer 214, the first conducting part 215, and the second conducting part 216. The planarization layer 217 is provided with a sixth through hole 224 and a seventh through hole 225. The sixth through hole 224 penetrates the planarization layer 217 to expose the first conducting part 215. The seventh through hole 225 penetrates the planarization layer 217 to expose the second conducting part 216.

The light-emitting structure layer 400 is disposed on the transistor layer 200. The light-emitting structure layer 400 includes a lower electrode 410 and the upper electrode 430 disposed in a stack. The lower electrode 410 is connected to the first electrode 212. The upper electrode 430 extends from the light-emitting area 11 to the non-light-emitting area 12. The orthographic projection of the first epitaxial part 2041 on the substrate 100 is the first projection. The orthographic projection of the upper electrode 430 on the substrate 100 is the second projection. The first projection at least partially overlaps the second projection.

Specifically, the light-emitting structure layer 400 is disposed on the transistor layer 200. The light-emitting structure layer 400 includes a lower electrode 410 and the upper electrode 430 disposed in a stack. The lower electrode 410 is connected to the first electrode 212. The upper electrode 430 extends from the light-emitting area 11 to the non-light-emitting area 12. Specifically, the light-emitting structure layer 400 includes a plurality of light-emitting structure parts. Each of the light-emitting structure parts is connected to one transistor. Each of the light-emitting structure parts includes the lower electrode 410, a light-emitting layer 420, and the upper electrode 430, that is, the light-emitting structure layer 400 includes the lower electrode 410, the light-emitting layer 420, and the upper electrode 430. The connecting electrode 218 and the lower electrode 410 are disposed on the planarization layer 217 in a same layer and spaced apart. The connecting electrode 218 extends into the sixth through hole 224 and is connected to the first conducting part 215. An orthographic projection of the connecting electrode 218 on the substrate 100 at least partially overlaps the first projection and the second projection, that is, the orthographic projection of the connecting structure on the substrate 100 at least partially overlaps the first projection and the second projection. The lower electrode 410 extends into the seventh through hole 225 and is connected to the second conducting part 216.

Subsequently, the pixel definition layer 300 is disposed on the planarization layer 217, the lower electrode 410, and the connecting electrode 218. The pixel definition layer 300 is provided with an auxiliary electrode hole 301 and a via 302. The auxiliary electrode hole 301 penetrates the pixel definition layer 300 to expose the connecting electrode 218. The auxiliary electrode hole 301 is provided corresponding to the metal conducting part 208 and the first epitaxial part 2041. The via 302 penetrates the pixel definition layer 300 to expose the lower electrode 410. The light-emitting layer 420 is disposed on the pixel definition layer 300 and extends into the auxiliary electrode hole 301 and the via 302 to connect with the connecting electrode 218 and the lower electrode 410 respectively. The light-emitting layer 420 is an organic light-emitting layer 420. The upper electrode 430 is disposed on the light-emitting layer 420 and extends into the auxiliary electrode hole 301. The upper electrode 430 located in the auxiliary electrode hole 301 is an auxiliary electrode. The second projection, the first projection, the third projection, and the orthographic projection of the connecting structure on the substrate 100 at least partially overlap. The lower electrode 410 is a reflective anode and the upper electrode 430 is a transparent cathode.

B12, connecting the epitaxial conductor part with the upper electrode.

When the light-emitting structure layer 400 of the panel to be repaired 20 has the poor bright-spots and needs to be repaired, by irradiating an overlapping region formed of the first projection, the second projection, the third projection, and the orthographic projection of the connecting structure on the substrate 100 with laser from a side of the substrate 100 away from the light-emitting structure layer 400, the interlayer dielectric layer 210 and the light-emitting layer 420 located in the overlapping region will melt due to the laser irradiating, thereby causing the first epitaxial part 2041, the metal conducting part 208, and the connecting structure to be connected to the upper electrode 430, so as to repair the panel to be repaired 20 to form the display panel 10.

Since the first electrode 212 is connected to the active part 205 and the lower electrode 410, therefore, the first epitaxial part 2041, the metal conducting part 208, the connecting structure, and the upper electrode 430 are conductive, which means that the upper electrode 430 is conductive with the lower electrode 410 to form a short-circuit between the upper electrode 430 and the lower electrode 410. Voltages at both ends of the light-emitting layer 420 is 0 V, the light-emitting layer 420 does not emit light, and the bright-spots are repaired to be dark-spots.

In an embodiment, power of the laser ranges from 300 ATT to 400 ATT. Specifically, the power of the laser can be 300 ATT, 340 ATT, 360 ATT, 380 ATT, or 400 ATT, etc.

In the present application, by disposing the first epitaxial part 2041 connected to the transistor, and the first projection, the second projection, the third projection, and the orthographic projection of the connecting structure on the substrate 100 being at least partially overlapping, so that when the panel to be repaired 20 has the poor bright-spots, the first epitaxial part 2041 can be connected to the upper electrode 430 under the laser irradiating, thereby repairing the poor bright-spots, reducing difficulty of repairing the poor bright-spots, and avoiding a waste of devices. At a same time, laser irradiating is only needed once to connect the first epitaxial part 2041 with the upper electrode 430, which can save a time required for repairing, thereby improving efficiency of repairing the poor bright-spots. Since the first epitaxial part 2041 is formed by extending the active part 205 to the non-light-emitting area 12, manufacturing process of the display panel 10 does not need to increase, which can shorten a production cycle, make it conducive to rapid preparation of the display panel 10, save a number of masks, and reduce production cost. By disposing the metal conducting part 208 on the first epitaxial part 2041, and the third projection, the second projection, and the first projection being at least partially overlapping, since the metal conducting part 208 is composed of metal, an electrical signal of the upper electrode 430 can be well transmitted to the first epitaxial part 2041, that is, it is easy to form a short-circuit between the first epitaxial part 2041 and the upper electrode 430, so as to further improve a success rate of repairing the poor bright-spots. In addition, the repairing method will not damage wiring of the transistor layer 200 or cause other defects, and repairing success rate is high.

In another embodiment, if the first epitaxial part 2041 is composed of the active part 205 extending towards the non-light-emitting area 12, and the second epitaxial part 2042 is composed of the light shielding part 201 extending towards the non-light-emitting area 12, when an overlapping region formed of the first epitaxial part 2041, the second epitaxial part 2042, the metal conducting part 208, the connecting structure, and the upper electrode 430 is irradiated by laser, the first epitaxial part 2041 can be connected to the second epitaxial part 2042, the metal conducting part 208, the connecting structure, and the upper electrode 430, so as to darken the bright-spots.

The present application provides the repairing method of the display panel. By disposing the epitaxial conductor part 204 connected to the transistor, the first epitaxial part 2041 is composed of the active part 205 extending towards the non-light-emitting area 12, and the first projection, the second projection, the third projection, and the orthographic projection of the connecting structure on the substrate 100 are disposed to be at least partially overlapping, or the first projection, the second projection, and the orthographic projection of the connecting structure on the substrate 100 are disposed to be at least partially overlapping, when the display panel 10 has the poor bright-spots, the first epitaxial part 2041 can be connected to the upper electrode 430 under the laser irradiating, so as to repair the poor bright-spots, reduce the difficulty of repairing the poor bright-spots, and avoid the waste of the devices. At a same time, laser irradiating is only needed once to connect the epitaxial conductor part 204 with the upper electrode 430, which can save the time required for repairing, so as to improve the efficiency of repairing the poor bright-spots. Since the first epitaxial part 2041 is composed of the active part 205 extending towards the non-light-emitting area 12, the manufacturing process of the display panel 10 does not need to increase, thereby shortening the production cycle, making it conducive to the rapid preparation of the display panel 10, saving the number of the masks, and reducing the production cost.

The present application provides the display panel 10 and the repairing method of the display panel 10. The epitaxial conductor part 204 is connected to the transistor, the epitaxial conductor part 204 is formed by extending the active part 205 towards the non-light-emitting area 12, and the epitaxial conductor part 204 and the active part 205 are formed by the same mask, which simplifies the manufacturing process of the epitaxial conductor part 204, thereby simplifying the manufacturing process of the display panel 10 and reducing the production cost. The epitaxial conductor part 204 is connected to the transistor, the epitaxial conductor part 204 is composed of the active part 205 extending towards the non-light-emitting area 12, and the first projection and the second projection are disposed to be at least partially overlapping. When the display panel 10 has the poor bright-spots, laser irradiating is only needed once to connect the epitaxial conductor part 204 with the upper electrode 430, which saves the time required for repairing, improves the efficiency of repairing the poor bright-spots, and reduces the cost. The auxiliary electrode hole 301 is provided in the pixel definition layer 300, the auxiliary electrode hole 301 is located directly above the epitaxial conductor part 204, so that when the poor bright-spots are needed to be repaired, the repairing points can be determined according to the position of the auxiliary electrode hole 301, so as to prevent the laser irradiating other metal layers or taking more time to find the repairing points, thereby improving the accuracy and the efficiency of repairing the poor bright-spots. The auxiliary electrode hole 301 is provided in the pixel definition layer 300, since the auxiliary electrode hole 301 passes through the pixel definition layer 300, the number of insulating layers that the laser needs to pass through can be further decreased, so as to improve the success rate of repairing the poor bright-spots.

The above describes the display panel and the repairing method of the display panel in the embodiments of the present application in detail. In this paper, specific examples are applied to explain a principle and implementation modes of the present application. The descriptions of the above embodiments are only used to help understand a method and a core idea of the present application; at a same time, for those skilled in the art, there will be changes in the specific implementation modes and an application scope according to the idea of the present application. In conclusion, contents of the specification should not be understood as restrictions on the present application.

What is claimed is:

1. A display panel, wherein the display panel comprises a plurality of sub-pixels, each of the sub-pixels comprises a light-emitting area and a non-light-emitting area disposed adjacent to each other, and the display panel comprises:
a substrate;
a transistor layer disposed on the substrate, wherein the transistor layer comprises a transistor and an epitaxial conductor part, the transistor is located in the light-emitting area, and the transistor comprises a first electrode and a second electrode disposed in a same layer and spaced apart: the epitaxial conductor part is located in the non-light-emitting area: the transistor further comprises an active part located below the first electrode: the epitaxial conductor part comprises a first epitaxial part, the active part is connected to the first epitaxial part, and the active part is connected to the first electrode or the second electrode; and
a light-emitting structure layer disposed on the transistor layer, the light-emitting structure layer comprises a lower electrode and an upper electrode disposed in a stack, the lower electrode is connected to the first electrode or the second electrode, and the upper electrode extends from the light-emitting area to the non-light-emitting area,
wherein an orthographic projection of the epitaxial conductor part on the substrate at least partially overlaps an orthographic projection of the upper electrode on the substrate.

2. The display panel according to claim 1, wherein the transistor further comprises a light shielding part located below the first electrode, the epitaxial conductor part further comprises a second epitaxial part, the light shielding part is connected to the second epitaxial part, and the light shielding part is connected to the first electrode or the second electrode.

3. The display panel according to claim 1, wherein the transistor further comprises a gate insulating part and a gate electrode, the first epitaxial part is composed of the active part extending towards the non-light-emitting area, and the gate insulating part and the gate electrode are sequentially stacked on the active part.

4. The display panel according to claim 3, wherein the transistor layer further comprises a metal conducting part, the metal conducting part is disposed between the first epitaxial part and the upper electrode, and the metal conducting part is spaced from the gate electrode; and the metal conducting part is connected to the first epitaxial part and insulated from the upper electrode, the gate electrode and the metal conducting part are manufactured by one process, and the metal conducting part, the first epitaxial part, and the upper electrode are disposed correspondingly.

5. The display panel according to claim 4, wherein the display panel further comprises a pixel definition layer, the pixel definition layer is disposed on the transistor layer and the lower electrode, the pixel definition layer is defined with an auxiliary electrode hole, and the auxiliary electrode hole is located in the non-light-emitting area; and the auxiliary electrode hole passes through the pixel definition layer, the auxiliary electrode hole is provided corresponding to the first epitaxial part and the metal conducting part, the upper electrode is disposed on the pixel definition layer, and the upper electrode extends into the auxiliary electrode hole.

6. The display panel according to claim 5, wherein the display panel further comprises a connecting structure, the connecting structure is disposed between the upper electrode and the metal conducting part, the connecting structure is insulated from the upper electrode and the metal conducting part, and the connecting structure, the first epitaxial part, the metal conducting part, and the upper electrode are disposed correspondingly.

7. The display panel according to claim 6, wherein the connecting structure comprises a connection electrode, the connection electrode is disposed on the transistor layer, and the connection electrode and the lower electrode are disposed in a same layer and spaced apart.

8. The display panel according to claim 7, wherein the connecting structure comprises a switching part and a first conducting part connected to the switching part, the switching part is disposed on a side of the first conducting part close to the upper electrode, and the switching part, the first electrode, and the second electrode are disposed in a same layer and spaced apart.

9. The display panel according to claim 8, wherein the transistor further comprises a light shielding part, the light shielding part is disposed corresponding to the active part, and the light shielding part is connected to the first electrode; and the first electrode is connected to an end of the active part and the upper electrode, the second electrode is connected to the first epitaxial part and another end of the active part, and an orthographic projection of the active part on the substrate is staggered with an orthographic projection of the first epitaxial part on the substrate.

10. A display panel, wherein the display panel comprises a plurality of sub-pixels, each of the sub-pixels comprises a light-emitting area and a non-light-emitting area disposed adjacent to each other, and the display panel comprises:
a substrate;
a transistor layer disposed on the substrate, wherein the transistor layer comprises a transistor and an epitaxial conductor part, the transistor is located in the light-emitting area, and the transistor comprises a first electrode and a second electrode disposed in a same layer and spaced apart: the epitaxial conductor part is located in the non-light-emitting area; and the transistor further comprises an active part located below the first electrode: the epitaxial conductor part comprises a first epitaxial part, the active part is connected to the first epitaxial part, and the active part is connected to the first electrode or the second electrode; and
a light-emitting structure layer disposed on the transistor layer, wherein the light-emitting structure layer comprises a lower electrode and an upper electrode disposed in a stack, the lower electrode is connected to the first electrode or the second electrode, the upper electrode extends from the light-emitting area to the non-light-emitting area, and the upper electrode is connected to the epitaxial conductor part.

11. The display panel according to claim 10, wherein the first epitaxial part is composed of the active part extending towards the non-light-emitting area: the transistor layer further comprises a metal conducting part, the metal conducting part is disposed on the first epitaxial part, and the metal conducting part is connected to the upper electrode and the first epitaxial part.

12. The display panel according to claim 11, wherein the transistor further comprises a gate insulating part and a gate electrode, the gate insulating part and the gate electrode are sequentially stacked on the active part, the gate electrode is spaced from the metal conducting part, and the gate electrode and the metal conducting part are manufactured by one process.

13. The display panel according to claim 12, wherein the display panel further comprises a pixel definition layer, the pixel definition layer is disposed on the transistor layer and the lower electrode: the pixel definition layer is defined with an auxiliary electrode hole, and the auxiliary electrode hole is located in the non-light-emitting area; and the auxiliary electrode hole passes through the pixel definition layer, the auxiliary electrode hole is provided corresponding to the first epitaxial part, the upper electrode is disposed on the pixel definition layer, and the upper electrode extends into the auxiliary electrode hole and is connected to the first epitaxial part.

14. The display panel according to claim 13, wherein the display panel further comprises a connecting structure, the connecting structure is disposed between the pixel definition layer and the first epitaxial part, and the connecting structure is connected to the upper electrode and the first epitaxial part.

15. The display panel according to claim 14, wherein the connecting structure comprises a connection electrode, the connection electrode is disposed on the transistor layer, and the connection electrode and the lower electrode are disposed in a same layer and spaced apart.

16. The display panel according to claim 15, wherein the connecting structure comprises a switching part and a first conducting part connected to the switching part, the switching part is disposed on a side of the first conducting part close to the upper electrode, and the switching part, the first electrode, and the second electrode are disposed in a same layer and spaced apart.

17. The display panel according to claim 15, wherein the transistor further comprises a light shielding part, the light shielding part is disposed corresponding to the active part, and the light shielding part is connected to the first electrode; and the first electrode is connected to an end of the active part and the upper electrode, the second electrode is connected to the first epitaxial part and another end of the active part, and an orthographic projection of the active part on the substrate is staggered with an orthographic projection of the first epitaxial part on the substrate.

18. The display panel according to claim 10, wherein the transistor further comprises a light shielding part located below the first electrode, the epitaxial conductor part further comprises a second epitaxial part, the light shielding part is connected to the second epitaxial part, and the light shielding part is connected to the first electrode or the second electrode.

19. A repairing method of a display panel, comprising:
providing a panel to be repaired, wherein the panel to be repaired comprises a plurality of sub-pixels, each of the sub-pixel comprises a light-emitting area and a non-light-emitting area disposed adjacent to each other, and the panel to be repaired comprises:
a substrate;
a transistor layer disposed on the substrate, wherein the transistor layer comprises a transistor and an epitaxial conductor part, the transistor is located in the light-emitting area, and the transistor comprises a first electrode and a second electrode disposed in a same layer and spaced apart; the epitaxial conductor part is located in the non-light-emitting area; the transistor further comprises an active part located below the first electrode; the epitaxial conductor part comprises a first epitaxial part, the active part is connected to the first epitaxial part, and the active part is connected to the first electrode or the second electrode; and
a light-emitting structure layer disposed on the transistor layer, the light-emitting structure layer comprises a lower electrode and an upper electrode disposed in a stack, the lower electrode is connected to the first electrode or the second electrode, and the upper electrode extends from the light-emitting area to the non-light-emitting area,
wherein an orthographic projection of the epitaxial conductor part on the substrate at least partially overlaps an orthographic projection of the upper electrode on the substrate; and
connecting the epitaxial conductor part with the upper electrode.

20. The repairing method of the display panel according to claim 19, wherein the step of connecting the epitaxial conductor part with the upper electrode comprises:
irradiating the epitaxial conductor part and the upper electrode by laser to connect the epitaxial conductor part with the upper electrode.
